(19) United States
(12) Patent Application Publication
(10) Pub. No.: US 2010/0066390 A1
(43) Pub. Date: Mar. 18, 2010

(54) CAPACITANCE VARIATION DETECTION CIRCUIT AND SEMICONDUCTOR DEVICE

(75) Inventors: Tatsuya Suzuki, Kumagaya-shi (JP); Yasuhiro Kaneta, Isesaki-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., MORIGUCHI CITY (JP); SANYO SEMICONDUCTOR CO., LTD., ORA-GUN (JP)

(21) Appl. No.: 12/449,721

(22) PCT Filed: Feb. 13, 2008
(86) PCT No.: PCT/JP2008/052287

§ 371 Date: Aug. 24, 2009

(30) Foreign Application Priority Data
Feb. 26, 2007 (JP) 2007-045011

(51) Int. Cl. G01R 27/26

(52) U.S. Cl. 324/686

(57) ABSTRACT

In a hybrid IC including, a semiconductor chip including a capacitance sensor and a semiconductor chip including a detection circuit for detecting a variation in capacitance, the number of bonding wires required between the chips is reduced. A rear surface of a sensor chip is connected to an electrode on a surface of a support substrate on which the sensor chip is mounted. A potential at one terminal of a capacitor of a sensor is set at a reference potential. A pad of another terminal is formed on a surface of the sensor chip. A detection circuit chip includes: a pad to serve as a connection terminal of the capacitor; a bias circuit connected to a terminal, for outputting a bias voltage to charge the capacitor; and a detection circuit connected to the terminal through a capacitor, for detecting a variation in potential of the terminal of the capacitor as an electrical signal. The chips are interconnected through a bonding wire between the pad of the terminal and the pad of the terminal.

### TECHNICAL FIELD

The present invention relates to a capacitance variation detection circuit for detecting a variation in capacitance of a capacitance sensor, and a semiconductor device including the sensor and the capacitance variation detection circuit.

### BACKGROUND ART

In recent years, attention has been focused on a MEMS microphone as one type of condenser microphone. A basic structure of the MEMS microphone includes a capacitor formed of two electrode plates including a diaphragm and a back plate, which are provided so as to face each other. The structure is formed on a silicon substrate by a micro electro mechanical systems (MEMS) technology. The MEMS microphone may be used for, for example, a hybrid integrated circuit (IC) in which a semiconductor chip of the MEMS microphone and a semiconductor chip of a capacitance variation detection circuit are mounted on a common support substrate.

FIG. 3 is a circuit diagram illustrating a conventional condenser microphone device. FIG. 4 is a schematic perspective view illustrating the conventional condenser microphone device provided as the hybrid IC. The device includes: a capacitor Cm serving as the MEMS microphone; and a bias circuit 2 and a detection circuit 4 which constitute a capacitance variation detection circuit for detecting a variation in capacitance of the capacitor Cm.

The bias circuit 2 applies a bias voltage Vbias to one terminal of the capacitor Cm. The detection circuit 4 is an inverting amplifier circuit which includes an operational amplifier 6 and a feedback resistor Rf, and is connected to the other terminal of the capacitor Cm. The detection circuit 4 receives at a terminal Vin, as an input signal, a variation in potential generated in the capacitor Cm according to a sound, amplifies the input signal, and outputs the amplified signal from a terminal Vout.

The MEMS microphone is formed in a semiconductor chip 10. The capacitance variation detection circuit is formed in a semiconductor chip 12. Both the semiconductor chips 10 and 12 are mounted on a support substrate 14 of an IC package to form the hybrid IC.

As illustrated in FIG. 4, bonding pads 16 and 18 connected to a diaphragm and a back plate, respectively, which constitute electrodes of the capacitor Cm, are provided on an upper surface of the semiconductor chip 10. Bonding pads 20 and 22, each serving as an output terminal Vbias of the bias circuit 2, and the input terminal Vin of the detection circuit 4 are provided on an upper surface of the semiconductor chip 12. In addition, the semiconductor chip 12 includes bonding pads 24, 26, and 28 which correspond to circuit power supply terminals Vdd and Vss and the output terminal Vout of the detection circuit.

A bonding wire 30 for connecting the bonding pads 18 and 20 to each other is provided between the semiconductor chips 10 and 12 to apply the bias voltage Vbias to the back plate of the capacitor Cm, and a bonding wire 32 for connecting the bonding pads 16 and 22 to each other is provided therebetween to input a variation in potential of the diaphragm of the capacitor Cm to the terminal Vin.

A reference potential Vss of the semiconductor chip 12 is set to a ground potential GND. The setting of Vss may be realized by, for example, wire-connecting the bonding pad 24 to a bonding pad 34 which is provided in the IC package and connected to external ground GND. The setting of Vss may also be realized by bonding an electrode which is provided on a surface of the support substrate 14 to a rear surface of the semiconductor chip 12 using a conductive paste.

Here, the back plate of the capacitor Cm is made up of a silicon substrate of the semiconductor chip 10 and fundamentally electrically connected to a rear surface of the semiconductor chip 10. As described above, the bias voltage Vbias is applied to the back plate, so the rear surface of the semiconductor chip 10 is required to be insulated from a surface electrode for supplying Vss of the support substrate 14. Therefore, the semiconductor chip 10 is bonded onto the support substrate 14 using an insulating paste 36.
Patent Document 1: JP 11-23609 A
Patent Document 2: JP 2003-148906 A

### DISCLOSURE OF THE INVENTION

### Problems to be Solved by the Invention

There are problems in that increases in the number of assembly steps and cost occur with an increase in the number of bonding wires required between the semiconductor chip 10 in which the capacitance sensor is provided and the semiconductor chip 12 in which the capacitance variation detection circuit is provided, and in that an increase in the number of connection points may reduce reliability.

The present invention has been made to solve the problems described above. An object of the present invention is to provide a capacitance variation detection circuit in which the number of bonding wires between chips may be reduced, and a semiconductor device including the circuit and a capacitance sensor.

### Means for Solving the Problems

A capacitance variation detection circuit according to the present invention is a circuit to be connected to a capacitance sensor, for detecting a variation in capacitance of a capacitor portion included in the sensor as an electrical signal, and includes: a terminal connected to one end of the capacitor portion; a bias circuit connected to the terminal, for outputting a bias voltage to charge the capacitor portion; and a detection circuit connected to the terminal through a DC decoupling capacitor, for detecting a variation in potential of the one end of the capacitor portion as the electrical signal.

A semiconductor device according to the present invention includes, on a common support substrate: a first semiconductor element including a capacitance sensor; and a second semiconductor element for detecting a variation in capacitance of a capacitor portion of the sensor as an electrical signal, in which the second semiconductor element includes: a bonding pad connected to one end of the capacitor portion by wire connection to the first semiconductor element; a bias circuit connected to the bonding pad, for outputting a bias voltage to charge the capacitor portion; and a detection circuit connected to the bonding pad through a DC decoupling capacitor, for detecting a variation in potential of the one end of the capacitor portion as the electrical signal, and in which the first semiconductor element has a rear surface which is electrically connected to a surface electrode provided on a surface of the support substrate, and which is supplied with a reference potential at another end of the capacitor portion, from the surface electrode.

### Effect of the Invention

According to the present invention, a signal path for supplying the bias voltage from the semiconductor chip (detection circuit chip) serving as the capacitance variation detection circuit to the semiconductor chip (sensor chip) serving as the capacitance sensor and a signal path for transferring the sensor output signal from the sensor chip to the detection circuit chip may be unified. In other words, the signal paths may be formed as a single bonding wire, so that the number of bonding wires is reduced compared to the conventional structure in which the signal paths are realized by separate bonding wire connections. Therefore, the number of assembly steps, and the cost, may be reduced and the improvement of reliability due to a reduction in the number of connection points is achieved. The number of bonding pads is also reduced, so each of the chips is reduced in size. Thus, a reduction in size of a semiconductor device including the sensor chip and the detection circuit chip is achieved. The sensor chip receives the reference potential to be used from the chip rear surface thereof as in the case of the detection circuit chip. That is, the rear surface of the sensor chip is not required to be insulated, so a distance from the detection circuit chip may be narrowed. In this regard, the size of the semiconductor device is further reduced.

### BRIEF DESCRIPTION OF THE DRAWINGS

FIG. 1 is a schematic circuit diagram illustrating a condenser microphone device according to an embodiment of the present invention.

FIG. 2 is a schematic perspective view illustrating a hybrid IC serving as the condenser microphone device according to the embodiment of the present invention.

FIG. 3 is a circuit diagram illustrating a conventional condenser microphone device.

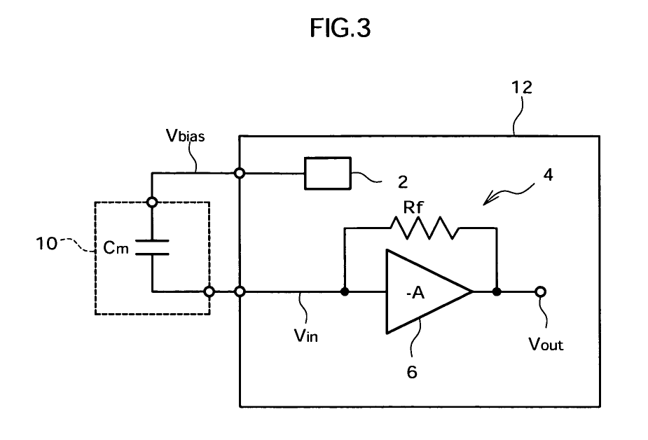

FIG. 4 is a schematic perspective view illustrating a hybrid IC serving as the conventional condenser microphone device.

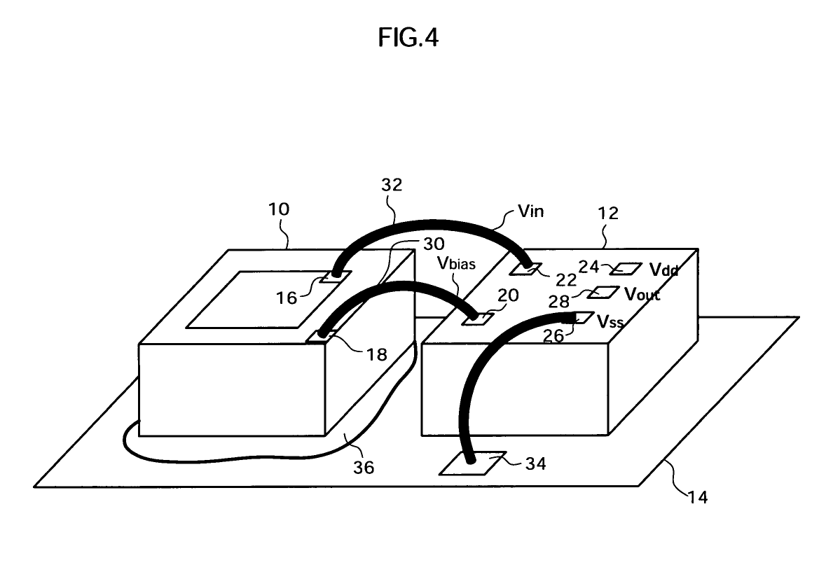

### BEST MODE FOR CARRYING OUT THE INVENTION

Hereinafter, an embodiment mode of the present invention (hereinafter referred to as embodiment) is described with reference to the attached drawings.

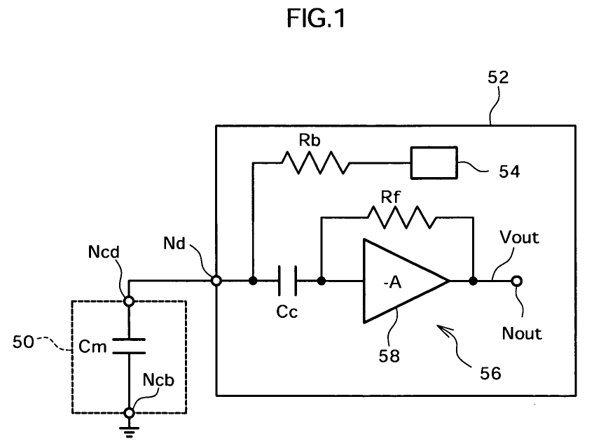

FIG. 1 is a schematic circuit diagram illustrating a condenser microphone device according to the embodiment. The device is a hybrid IC in which a MEMS microphone is used as a condenser microphone, and a sensor chip 50, which is a semiconductor element including the MEMS microphone, and a detection circuit chip 52, which is a semiconductor element including a circuit for detecting a variation in capacitance of the MEMS microphone, are mounted on a package.

The MEMS microphone formed in the sensor chip 50 has a capacitor portion including a diaphragm and a back plate as electrode plates. In FIG. 1, which is the circuit diagram, the capacitor portion is expressed as a capacitor Cm. A back plate side terminal Ncb of the capacitor Cm is grounded to GND and a diaphragm side terminal Ncd thereof is connected to a terminal Nd of the detection circuit chip 52.

The capacitance variation detection circuit formed in the detection circuit chip 52 includes: a bias circuit 54 connected to the terminal Nd, for outputting a bias voltage Vbias to charge the capacitor Cm; and a detection circuit 56 connected to the terminal Nd through a DC decoupling capacitor Cc, for detecting a variation in potential of the terminal Ncd of the capacitor Cm as an electrical signal.

The bias circuit 54 includes, for example, a charge pump circuit and generates the bias voltage Vbias, which is a high voltage necessary to drive the MEMS microphone, by a step-up operation from a reference power supply voltage Vdd supplied to the detection circuit chip 52. The generated bias voltage Vbias is applied to the terminal Nd through a resistor Rb. The bias voltage Vbias is applied from the detection circuit chip 52 to the terminal Ncd of the capacitor Cm. The capacitor Cm is charged based on a voltage between the terminal Ncd and the terminal Ncb applied with a ground potential GND.

The detection circuit 56 is an inverting amplifier circuit including an operational amplifier 58 and a feedback resistor Rf . An inverting input terminal of the operational amplifier 58 is connected to the terminal Nd through the capacitor Cc. When the diaphragm of the MEMS microphone is displaced according to a sound, a capacitance value of the capacitor Cm changes to change a voltage Vm between the terminals of the charged capacitor Cm. Because the terminal Ncb is fixed at the ground potential GND, a potential of the terminal Ncd becomes Vm and then the voltage Vm is transferred as an output signal of the MEMS microphone to the terminal Nd of the detection circuit chip 52. A temporal change in voltage signal Vm due to the displacement of the diaphragm, that is, an alternating current component, passes through the capacitor Cc and is transferred to the inverting input terminal of the operational amplifier 58. The detection circuit 56 outputs, as a sound signal, a voltage signal Vout obtained by amplifying the alternating current component of the voltage Vm, from a terminal Nout to a signal processing circuit in the subsequent stage.

The resistor Rb connected in series between the bias circuit 54 and the terminal Nd is set at a high resistance to suppress a current flowing between the terminal Nd and the bias circuit 54 due to the change in voltage Vm. Therefore, a reduction in gain of the alternating current signal transferred to the operational amplifier 58 through the capacitor Cc is prevented.

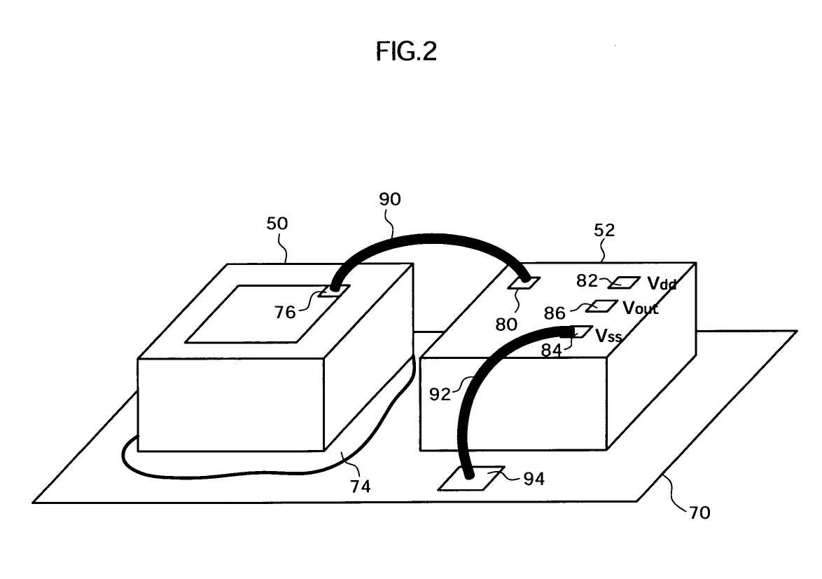

FIG. 2 is a schematic perspective view illustrating the condenser microphone device provided as the hybrid IC. The sensor chip 50 and the detection circuit chip 52, each of which is made up of a silicon substrate, are placed on a common support substrate 70. A back plate of the sensor chip 50 is electrically connected to a rear surface of the sensor chip through the silicon substrate, and the rear surface serves as the terminal Ncb of the capacitor Cm. Therefore, the terminal Ncb is not provided on an upper surface of the sensor chip 50. A surface electrode connected to GND is formed on a surface of the support substrate 70. The sensor chip 50 is bonded to the support substrate 70 using a conductive paste 74. The ground potential GND is applied from the surface electrode to the rear surface of the sensor chip 50. Thus, a potential of the terminal Ncb is set to the ground potential GND.

The diaphragm is formed on the surface of the sensor chip 50 and a bonding pad 76 is formed as the terminal Ncd connected to the diaphragm on the surface thereof.

Circuits including the bias circuit 54, the detection circuit 56, and the like as illustrated in FIG. 1 are formed on a surface of the detection circuit chip 52. Bonding pads 80 to 86 serving as terminals of the circuits are provided on the surface of the detection circuit chip 52 illustrated in FIG. 2. The bonding pad 80 serves as the terminal Nd. The bonding pads 76 and 80 are connected to each other through a bonding wire 90. Therefore, the sensor chip 50 and the detection circuit chip 52 are connected to each other, so that the bias voltage Vbias may be applied from the bias circuit 54 to the capacitor Cm and the variation in voltage Vm of the capacitor Cm may be detected and amplified by the detection circuit 56.

The bonding pads 82 and 84 are terminals for supplying power supply voltages Vdd and Vss to the circuits. For example, the bonding pad 84 is connected through a bonding wire 92 to a bonding pad 94 located on the support substrate 70, to receive the ground potential GND as Vss supplied from the surface electrode located on the support substrate 70. As in the case of the sensor chip 50, the detection circuit chip 52 may also be configured to receive the ground potential GND as Vss supplied from a rear surface thereof. In such a case, the support substrate 70 may include surface electrodes connected to the rear surface of the sensor chip 50 and the rear surface of the detection circuit chip 52. As in the case of the sensor chip 50, the detection circuit chip 52 may also be formed such that the rear surface thereof is connected to the surface electrode by a conductive paste.

The bonding pad 82 is connected to a pin of the package through a bonding wire (not shown) and applied with the voltage Vdd supplied from an external circuit to the pin. The bonding pad 86 serves as the output terminal Nout of the detection circuit 56 and is connected to a pin of the package through a bonding wire (not shown) to be able to output the voltage signal Vout from the pin to a circuit in the subsequent stage.

In this embodiment, the structure using the MEMS microphone is described. The present invention may be applied to other structures using the capacitance sensor.

1. A capacitance variation detection circuit to be connected to a capacitance sensor, for detecting a variation in capacitance of a capacitor portion included in the sensor as an electrical signal, comprising:
a terminal connected to one end of the capacitor portion;
a bias circuit connected to the terminal, for outputting a bias voltage to charge the capacitor portion; and
a detection circuit connected to the terminal through a DC decoupling capacitor, for detecting a variation in potential of the one end of the capacitor portion as the electrical signal.

2. A semiconductor device comprising, on a common support substrate:
a first semiconductor element including a capacitance sensor; and
a second semiconductor element for detecting a variation in capacitance of a capacitor portion of the sensor as an electrical signal,
wherein the second semiconductor element comprises:
a bonding pad connected to one end of the capacitor portion by wire connection to the first semiconductor element;
a bias circuit connected to the bonding pad, for outputting a bias voltage to charge the capacitor portion; and
a detection circuit connected to the bonding pad through a DC decoupling capacitor, for detecting a variation in potential of the one end of the capacitor portion as the electrical signal, and
wherein the first semiconductor element has a rear surface which is electrically connected to a surface electrode provided on a surface of the support substrate and which is supplied with a reference potential to another end of the capacitor portion, from the surface electrode.

3. A semiconductor device according to claim 2, wherein each of the first semiconductor element and the second semiconductor element is bonded to the surface electrode through a conductive paste.
